(19) United States
(12) Patent Application Publication
(10) Pub. No.: US 2018/0102427 A1
(43) Pub. Date: Apr. 12, 2018

(54) SINGLE STRUCTURE CASCODE DEVICE

(71) Applicant: QUALCOMM Incorporated, San Diego, CA (US)

(72) Inventors: Fabio Alessio MARINO, San Marcos, CA (US); Paolo MENEGOLI, San Jose, CA (US)

(21) Appl. No.: 15/840,961

(22) Filed: Dec. 13, 2017

Related U.S. Application Data
(63) Continuation of application No. 12/930,497, filed on Jan. 10, 2011.

(51) Int. Cl. H01L 29/778; H01L 29/78; H01L 29/40; H01L 29/423; H01L 29/417

(52) U.S. Cl. CPC H01L 29/7787; H01L 29/7838; H01L 29/7835; H01L 29/7831; H01L 29/42316; H01L 29/41775; H01L 29/407; H01L 29/402

(57) ABSTRACT

A novel semiconductor power transistor is presented. The semiconductor structure is simple and is based on a MOS configuration with a drift region and an additional gate that modulates the carrier density in the drift region, so that the control on the carrier transport is enhanced and the specific on-resistance per area is reduced. This characteristic enables the use of short gate lengths while maintaining the electric field under the gate within reasonable values in high voltage applications, without increasing the device on-resistance. It offers the advantage of extremely lower on-resistance for the same silicon area while improving on its dynamic performances with respect to the standard CMOS technology. Another inherent advantage is that the switching gate losses are smaller due to lower V_{GS} voltages required to operate the device.

### CLAIM OF PRIORITY UNDER 35 U.S.C. § 119

This application is a continuation application of, and claims the benefit of priority from, U.S. patent application Ser. No. 12/930,497, filed Jan. 10, 2011, which is assigned to the assignee hereof and hereby expressly incorporated by reference herein.

### BACKGROUND

### Field of the Invention

The present invention is in the field of semiconductor structures. The present invention is further in the field of semiconductor structures of transistor devices. The present invention further relates to the field of integrated and non-integrated power devices and circuits. The implementation is not limited to a specific technology, and applies to either the invention as an individual component or to inclusion of the present invention within larger systems which may be combined into larger integrated circuits.

### Relevant Background

The semiconductor transistor is the most important component for large integrated circuits. The complementary CMOS components used in current integrated circuit process technologies have undergone a continuous shrinking of the silicon area needed for elementary components, however the need to further improve on its general performance while reducing its cost is still a necessity that poses a significant challenge.

In particular, in the area of power integrated circuits the silicon area occupied by the power transistors and their performance is more and more important in several applications. A very critical parameter for power transistors in integrated circuits is their specific R_{DSon}, measured in Ω*rnm². The silicon area is directly proportional to the cost of the integrated circuit and a low on-resistance is always desirable to increase the efficiency of the circuit and to reduce the power dissipation and therefore the temperature of the chip.

The most important Figure Of Merit (FOM) of a power transistor in specific power applications is the R_{DSon}*Q of the transistor, where R_{DSon} is the on-resistance while Q is the charge associated with the gate capacitance (C*V). This FOM is directly associated with the time constant of the device. The lower the R_{DSon} and the gate charge, the higher the achievable efficiency.

Typically the power transistors utilized in modem integrated circuits are constituted by large arrays of MOSFET devices effectively connected in parallel. In addition to high-voltage and high-current capability, these devices also have low on-state power losses and good switching characteristics (e.g. fast switching with minimal switching losses etc.) in order to maximize the figure of merit (R_{DSon}*Q) discussed above.

The typical cross-sections of a conventional MOSFET is illustrated in FIG. 1. In general, power MOSFETs employ thicker oxides, deeper junctions, and have longer channel lengths with respect to signal MOS devices. This generally poses a penalty on the device performance such as lower transconductance and speed, which are strictly correlated to the Figure of Merit described above (R_{DSon}*Q).

Several prior art attempts to improve power MOSFET performance, so as to effectively obtain low on-resistance components with low parasitic capacitances, have been documented. In particular, a device often used in power applications, which shows several advantages over the conventional MOS structure, is the Laterally Diffused MOS (LDMOS).

A typical cross-sections of an LDMOS is shown in FIG. 2. Differently from a standard MOS, in the LDMOS transistor the channel length is determined by the higher diffusion rate of the p-doping (e.g. boron) compared to the n+-doping (e.g. phosphorus) of the source. This technique can yield very short channels independently from the lithographic mask dimension.

The p-diffusion serves as channel doping and offers good punch-through control. The channel is followed by a lightly doped n•-drift region. This drift region is long compared to the channel, and it minimizes the peak electric field in the device channel. The electric field near the drain is the same as in the drift region, so the avalanche breakdown, multiplication, and oxide charging are lessened compared to conventional MOSFETs.

Such doping configuration enables the p-doped substrate to deplete this drift region at high drain bias. Yet at low drain bias its n-doping gives lower series resistance. This drift diffusion thus behaves as a non linear resistor. At low drain bias, its resistance is determined by 1/nqμ, where n is the doping concentration, q is the elementary charge, and μ is the electron mobility in the semiconductor. At high drain bias, this region is fully depleted so a large voltage drop can be supported. This concept is called RESURF (reduced surface field) technology.

Lateral Diffused MOSs, and in general MOS devices with drain extensions, are advantageous with respect to standard CMOS devices since they have low gate capacitance but they can still support high drain bias. However, this advantage comes at the cost of the on-resistance which is higher than in standard MOSFETs due to the low doping concentration of the drift region.

Thus nowadays, no single device that offers combined benefits of a MOSFET (low forward voltage drop for high voltage applications) and a LDMOSFET (fast switching) exists.

An interesting prior art attempt to reduce the parasitic capacitance using two MOSFETs connected in series is the cascode circuit. In this configuration, only one of the two transistors (i.e. the input FET) is used to tum on and off the resulting series. The gate of the other one (i.e. the output FET) is kept at a fixed voltage.

The major advantage of this circuit arrangement stems from the fact that only one gate capacitance must be charged and discharged in order to turn on and off the series of the two devices. This feature allows the cascade to sustain high output biasing, maintaining a low on-resistance and low parasitic capacitances. Furthermore, the cascode configuration dramatically reduces the Miller feedback capacitance from the input FET gate to the output swing node.

The main purpose of the present invention is to describe a novel structure of a power semiconductor transistor based on a MOS configuration, with a drain extension and an additional gate, which combines the advantages of an LDMOS with the advantages of a cascode circuit, without requiring two separated devices. The drift region allows the device to sustain high drain bias maintaining a low gate capacitance, while the extra gate reduces the on-resistance of the overall device.

This device, therefore, offers the advantage of reducing silicon area and cost combined with improved performance in terms of on-resistance and gate capacitance with respect to both conventional MOSFET and LDMOS devices.

Generally the extra gate configuration has been used in semiconductor transistors only as a Field Plate, i.e. to reduce the channel electric field in the device, so as to effectively decrease the degradation of the device due to Hot Carrier Injection (HCl) phenomena and increase the device breakdown voltage, or as a Shielding electrode between the gate and the drain terminals in order to reduce the parasitic device capacitance.

A field plate, located between gate and drain electrodes but adjacent to the gate, extends the depletion edge from the gate-drain edge to the semiconductor region under the field-plate, shifts the peak electric field from the gate edge in the semiconductor to the field plate edge in the dielectric, and reduces the electric field at the gate-drain edge. In addition, surface trap effects can be suppressed dramatically, resulting in an increased available RF current at the open channel condition.

The field plate concept has been widely investigated in literature particularly for High Electron Mobility Transistor applications, but lately it found interesting applications also in LDMOS structures. For example, in Feilchenfeld et al. (US 2009/0140343) the authors propose a field plate formed in a silicon trench in order to obtain an LDMOS structure in which the drift region length is independent from the overlay variations of the lithographic steps in the manufacturing process.

Another example is reported in Gammel et al. (U.S. Pat. No. 7,820,517), where the authors propose to use a dummy gate field plate in an LDMOS structure in order to decrease the on-resistance degradation due to HCl effects, that take place when an LDMOS is used in high power applications for an extended period of time. Similar approach is proposed in Yang et al. (U.S. Pat. No. 7,795,674) where the extra gate is connected to the space charge region of a diode in order to be biased.

As is well known, the HCl phenomenon generally results from heating and subsequent injection of charge carriers into the gate oxide and/or an oxide layer above a drift region of an LDMOS device. This injection of charge carriers often results in a localized and non-uniform build-up of interface states and oxide charges near and underneath a gate and/or in the drift region of the device.

As mentioned above, the dummy gate has been used in prior art devices also to shield the drain from the gate in order to decrease the gate to drain capacitance. An example of a shielding plate that has been used in a LDMOS device is presented in Hebert (U.S. Pat. No. 6,215,152). In this patent the author proposes a buried shielding plate approach in order to maximize the shielding effect.

Although all the examples of cited prior art combine a LDMOS structure with an extra gate terminal, they are intended only to reduce the degradation phenomena in the device so as to improve its reliability and/or reduce the gate to drain capacitance of the device. In order to achieve these objectives, the added electrode is just a field plate or shielding plate and not a gate terminal, meaning that its gate-oxide is thicker than the main gate-oxide in order to avoid a deterioration of the gate to drain parasitic capacitance. The control of the dummy gate on the carrier transport is therefore very limited.

The main purpose of the present invention is to describe a novel structure of a semiconductor transistor for power circuit applications, with an extra gate terminal, that offers the advantage of LDMOS structures with much lower on-resistance. The added gate is a true gate terminal with full control on the carrier transport in the device. Furthermore, the extra terminal is never short-circuited with the main gate terminal (as it is often done in the field plate configuration) and it can be connected to a supply voltage, or to the ground based on the application.

### SUMMARY

The present invention describes a power transistor which has a MOS structure with drain extension, with an additional gate terminal that controls the carrier density in the drift region. This characteristic enables the use of short gate lengths while maintaining the electric field underneath the gate-drain edge within reasonable values in high voltage applications, without increasing the device on-resistance. Another inherent advantage is that the switching gate losses are smaller due to lower Vas voltages required to operate the device.

In order to better understand this concept, let us consider the structure illustrated in FIG. 3, which represents a cross-section of the preferred embodiment of the present invention. As it can be seen, conventional device terminals (source, gate, drain and body) are present as in a conventional MOS device. However, a drift diffusion region and an extra gate terminal have been added to the structure.

As mentioned above, the drift region minimizes the peak electric field in the device channel improving the reliability of the device in high voltage applications. The field near the drain is the same as in the drift regions, so avalanche breakdown, multiplication, and oxide charging are lessened compared to conventional MOSFETs.

The extra gate 17 is used to enhance the carrier concentration in the drift region during the on-state operation of the device, and/or to deplete the drift region under it during off-state conditions. When the main purpose of the extra gate is to enhance the carrier concentration in the drift region during the on-state operation of the device, the gate region 17 is preferably made in n-type poly-silicon (for an n-channel device) so as to allow a strong reduction of the device on-resistance.

While, in the case in which the main function of the extra gate is to deplete the drift region during off-state conditions, a p-type poly-silicon (for an n-channel device) is preferably used and the drain extension can be designed with shorter lengths and/or with a lower doping concentration with respect to a conventional LDMOS, maintaining the high voltage tolerance of the structure. Furthermore, the depletion of the drift region, that takes place when the device is turning off, leads to the reduction of the main gate to drain capacitance of the device. Obviously in both cases described above, the extra gate terminal can be realized also with metallic materials with an appropriate work-function.

The structure of FIG. 3, therefore, combines the advantages of a LDMOS device, structure which is able to sustain high drain bias maintaining a low gate capacitance, with the low on-resistance of standard MOS devices connected in cascode configuration. Furthermore, in the structure of the present invention, the drain to gate capacitance is reduced which leads to an even higher improvement of the dynamic device performance.

The extra gate terminal can be connected in different ways. All of them have advantages and disadvantages which must be carefully evaluated, based on the device application. For example, one possible configuration is to connect the extra gate directly to the main gate and drive the two terminals together. However, this operation is not suggested, since it increases significantly the gate drive capacitance of the device, which is unacceptable in most applications. Another means of controlling the second gate is to connect it directly to a supply voltage or ground, and switch only the main gate so that the charging and discharging of the gate capacitance is limited to the main gate only.

By connecting the extra gate to a supply voltage, the extra gate mainly enhances the drift region of electrons when the device is turned on reducing the on-resistance of the device. When the transistor is in off-state the device behaves as a conventional MOS device with a drain extension. Instead, by connecting the extra gate to ground, it mainly depletes the drift region when the device is turned off reducing the gate to drain capacitance. The depletion effect of the extra gate enables the device to sustain a much higher drain bias with respect to a standard MOS device with drain extension. This feature introduces a new degree of freedom in the design of the drift region, which can be made shorter while maintaining the channel electric field in the safe range. When the transistor is in on-state the device behaves as a conventional MOS device with a drain extension.

When used in switching power converters, the second gate can be also coupled to ground through a capacitor of adequate value. This is possible since the average of the capacitive current in the second gate is null throughout a period of switching, allowing an increase of the device efficiency since no energy is dissipated in the second gate. By connecting the capacitor to a high impedance node for the initial voltage (e. g. a resistor divider from Vin to ground) the drive circuit of the device is much simplified. Alternative schemes are also possible as known to anyone skilled in the art.

Another interesting configuration is obtained when the second gate is short-circuited with the drain terminal. In this case the capacitance between the drain and the second gate is completely eliminated and the dynamic performance of the device is greatly improved. However, in this case, the advantage in terms of DC on-resistance is less evident with respect to the previous configurations.

The present invention in the embodiment depicted in FIG. 3 can be obtained with a standard CMOS process. The second gate can be formed in parallel with the first one simply modifying the masks layout, since the same gate oxide can be used for both gate electrodes. This makes the present invention very cost attractive.

Another interesting method to implement this embodiment is to exploit the spacer of the first gate to determine the location where the second gate is formed. Starting from a conventional MOSFET with a drain extension where the first gate region has already been formed and the gate oxide layer has not been etched from the device surface, the second gate can be formed by means of a simple deposition step followed by a polish and an etch process steps to remove the deposited material from the undesired area. The advantage of this second technique is that the distance of the second gate from the first one is independent from the technology node. Obviously many other process variants can be used to obtain the embodiment described above. Similar process considerations apply also for all the other embodiments described below.

In addition to the MOS structure of FIG. 3, the present invention can be realized also with the Lateral Diffusion MOS configuration illustrated in FIG. 4. In this case the device is obtained from a LDMOS structure by simply adding an extra gate. The advantage of this structure is that the gate length of the device is determined by the implantation characteristic instead of the minimum lithography feature of the technology used in the device fabrication process. Another inherent feature of the structure depicted in FIG. 4 is that the laterally diffused channel has a graded doping profile, which improves the device transconductance, and helps prevent the punch-through.

In order to increase the carrier mobility in the device, the channel region can be doped with very low concentrations of p-type impurities or with n-type doping as illustrated in FIG. 5. In this case, the impurity scattering and the surface roughness scattering rates are greatly reduced. Using a p-doped poly-silicon gate layer for the first gate, instead of the classical n-doped one, the semiconductor device assumes a positive threshold voltage and behaves as an enhancement MOS transistor.

As illustrated in FIG. 6 the structures discussed above can be realized also with a buried second gate. This configuration allows the reduction of the capacitive coupling between the two gates of the device, improving the dynamic performance of the device.

All the structures discussed above can be realized in many variants as shown in the following. For example, the extra gate can be directly connected to the source of the device through a metal (or heavily doped poly-silicon) layer as shown in FIG. 7. In this case the metal (or heavily doped poly-silicon) layer reduces the coupling between the main gate and the drain terminal improving the device performance.

Another interesting embodiment of the invention is illustrated in FIG. 8. In this case a thin dielectric layer has been added between the second gate and the metal (or heavily doped poly-silicon) layer. In this configuration the device has the second gate coupled to the source through the intrinsic capacitor composed by the regions 68, 69, and 70. By connecting the second gate to a high impedance for the initial setting up voltage (e. g. a resistor divider from Vin to ground) the resulting device can be turned on and off driving only the main gate, therefore reducing the switching losses.

FIG. 9 shows another embodiment of the invention, where the extra gate has been directly connected to the drain through a metal (or heavily doped poly-silicon) layer. This structural solution is very elegant and allows a strong improving of the dynamic device performance. The extra-gate to drain capacitance has been eliminated, which offers a great advantage in the dynamic device behavior. However, in this case the advantage in terms of on-resistance is less evident with respect to the previous configurations.

In all the structures discussed herein, the drift region under the second gate can be eliminated in order to reduce the capacitive coupling between the second gate and the drain terminal. In this case the device has two drift regions spaced apart one from the other.

In addition to the MOS technology configurations shown above, the present invention can be realized also in High Electron Transistor Technology, including III-V compounds semiconductor materials of the periodic table in the fabrication process as depicted in FIG. 10. In this case the gate 96 can be doped n or p depending on the application. If the gate 96 is p-doped, the resulting device is an enhancement mode FET, while if it is doped with n-type impurities (or it is made of metallic materials in order to form a Schottky contact with the semiconductor layer 92), the device works in depletion mode. For the second gate 88, the same considerations, derived for the case of the MOS technology, still apply.

For all the FET structures described above, the p-channel version can be obtained by simply substituting the n-doped implants with p-type ones and vice-versa. As it is clear to those skilled in the art, the present invention can be used also in discrete devices and/or in vertical FET structures with simple modifications.

It is therefore an object of the present invention to increase the packing density and to improve the device performance by using an extra gate and a drift region with respect to standard MOS devices. It is a further object of the invention to increase the speed of the transistor by reducing the parasitic capacitances and the device on-resistance.

In FIGS. 11, 12 and 13 the voltage and current waveforms, as result of the numerical simulation are shown. In this analysis, a comparison was performed between a conventional n-channel MOS with a drain extension and the same device, three times smaller, with an extra gate according to the preferred embodiment of the invention. A resistive load was placed between the drain and a supply voltage of 5V and a pulse voltage signal varying between 0 and 2.5V has been applied to the main gate terminal. In this analysis the second gate has been coupled to the ground through an external capacitor of 100 pF, while the load resistance used was 5 Ohms. The devices, according to the present invention and the conventional MOS with drain extension, have a channel width of 1.6 and 5 mm, respectively. Both devices have a gate length of 0.25 μm.

As it can be seen from FIG. 11, where the drain voltage as a function of time is illustrated, the two simulated devices have the same on-resistance, even if the one according to the present invention (solid line 99) occupies less than one third of the silicon area required by the conventional MOS device (dashed line 98). The drift region length and doping concentrations are the same in both devices and they were designed to maintain the voltage under the gate-drain edge around 2.5-3V. As it can be seen from FIG. 12, which illustrates the voltage in the drift region in proximity of the lateral edge of the first gate of each device, the voltage drop on the first portion of the device, in the case of the present invention (solid line 101), is even smaller than in the case of a conventional MOS with drain extension (dashed line 100).

It is important to notice that also the gate current and therefore the switching losses of the present invention are reduced by a factor 3 or more as shown in FIG. 13. The peak of the gate current (solid lines 103) in the device according to the present invention is much smaller if compared with the one of the conventional MOS with drain extension (dashed line 102). As demonstrated by the numerical simulation, the present invention improves the device performance by a factor 3 or more, which leads to a great reduction of the device cost when implemented in power circuit applications.

As it is clear to those skilled in the art, this basic system can be implemented in many specific ways, and the above descriptions are not meant to designate a specific implementation.

### BRIEF DESCRIPTION OF THE DRAWINGS

The features, objects, and advantages of the present invention will become apparent upon consideration of the following detailed description of the invention when read in conjunction with the drawings in which:

FIG. 1 shows a cross section view of a conventional MOSFET built in CMOS technology (prior art).

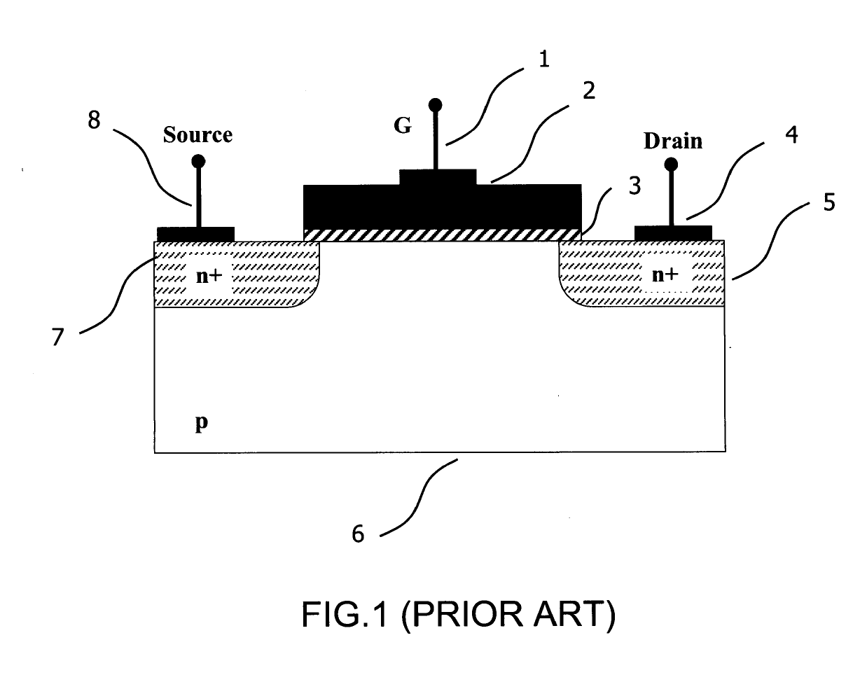

FIG. 2 shows a cross section view of a Lateral diffused MOS, where a drift region is present in order to decrease the electric field inside the device in high voltage applications (prior art).

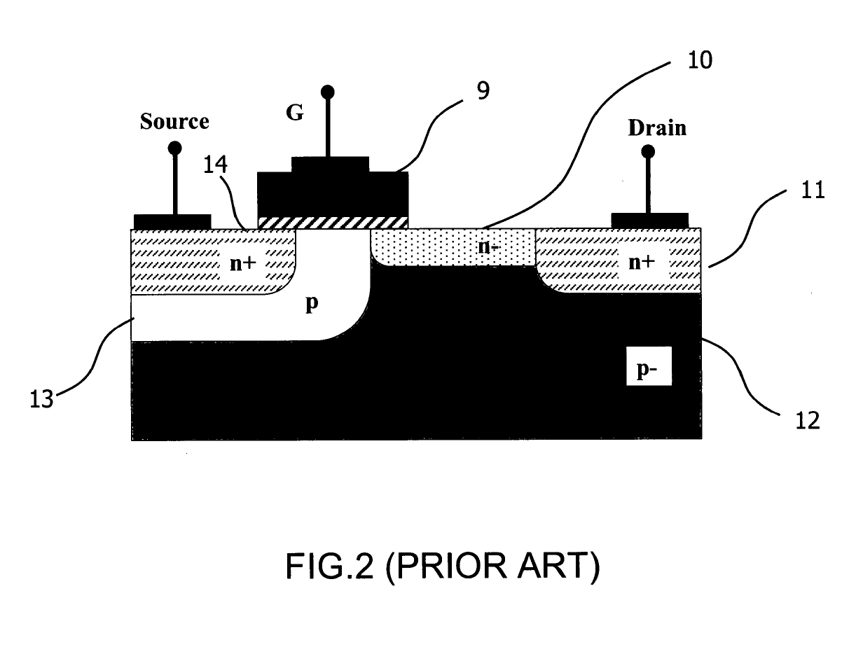

FIG. 3 shows a cross section view of a semiconductor device with drain extension according to the preferred embodiment of the invention.

FIG. 4 shows a cross section view of a semiconductor device according to a second embodiment of the invention based on a Lateral Diffusion MOS structure.

FIG. 5 shows a cross section view of a high mobility device according to a third embodiment of the invention.

FIG. 6 shows a cross section view of a semiconductor device with a second buried gate and a buried drift region according to a fourth embodiment of the invention.

FIG. 7 shows a cross section view of a semiconductor device with the second gate short-circuited to the source by means of a metal (or heavily doped poly-silicon) deposition layer according to a fifth embodiment of the invention.

FIG. 8 shows a cross section view of a semiconductor device with the second gate coupled to the source by means of a dielectric layer and a metal (or heavily doped poly-silicon) deposition layer forming a capacitor according to a sixth embodiment of the invention.

FIG. 9 shows a cross section view of a semiconductor device with the second gate short-circuited to the drain by means of a metal (or heavily doped poly-silicon) deposition layer according to a seventh embodiment of the invention.

FIG. 10 shows a cross section view of a High Electron Mobility Transistor (HEMT) device with a second gate according to an eighth embodiment of the invention.

FIG. 11 shows the drain voltage as result of the numerical simulation of a conventional MOS with a drain extension and the same device, three times smaller, with an extra gate according to the preferred embodiment of FIG. 3 of the invention.

FIG. 12 shows the drift region voltage near the main gate as result of the numerical simulations for a conventional MOS with a drain extension and the same device three times smaller, with an extra gate according to the preferred embodiment of the invention of FIG. 3.

FIG. 13 shows the gate current as result of the numerical simulations for a conventional MOS with a drain extension and the same device, three times smaller, with an extra gate according to the preferred embodiment of the invention of FIG. 3.

### DETAILED DESCRIPTION

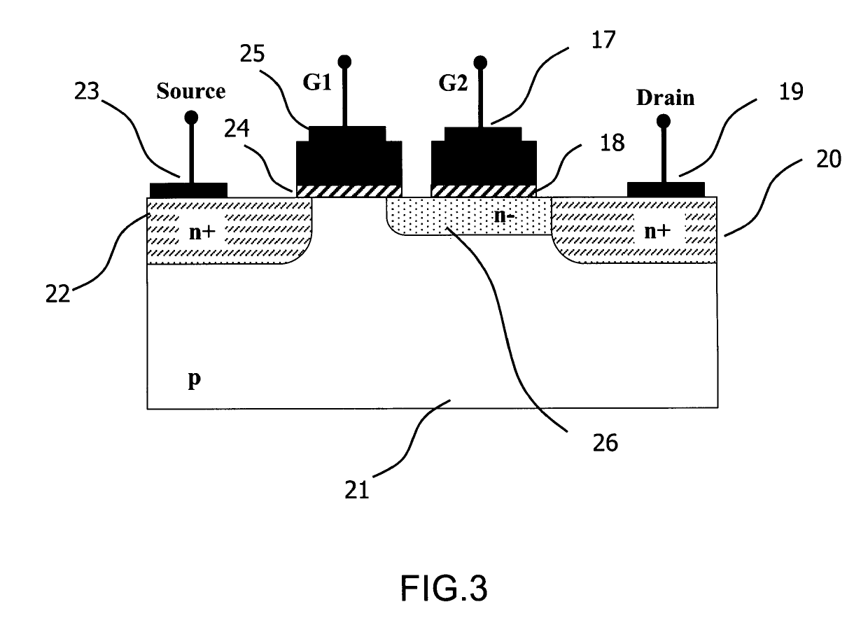

### A FIG. 3

FIG. 3 shows the preferred embodiment of the invention. The n⁺-type region 22 defines the source region whereas the n⁺-type region 20 forms the drain of the transistor. The regions 24 and 18 correspond to the gate-oxide layers, and region 21 is the p-type substrate of the device. The gate electrodes (or terminals) 25 and 17, which may be built in poly-silicon or metal, represent the first and the second gate regions of the transistor, respectively. A drift region 26, which extends from the first gate to the drain terminal, is present under the second gate-oxide 18.

As it can be seen, the structure of FIG. 3 is similar to the one of a conventional MOS, with the exception that the drift region 26 and the extra gate 17 have been added to the structure. The drift region minimizes the peak electric field in the device channel improving the reliability of the device in high voltage applications. The field near the drain is the same as in the drift regions, so avalanche breakdown, multiplication, and oxide charging are lessened compared to conventional MOSFETs. The extra gate 17 is then used to modulate the carrier concentration in the drift region in order to enhance the electron population when the device is in on-state conditions, and/or deplete the region under it when the device is turned off

The structure resulting by the combination of the extra gate 17 with the drain extension 26 can be viewed as a depletion MOS transistor connected in series to an enhancement n-channel MOS device driven by the main gate 25. The device depicted in FIG. 3 behaves therefore as a cascode MOS circuit with a depletion MOS as output device.

In order to understand this concept, let us consider the case in which the extra gate 17 is connected to a supply voltage of 2.5V, while the first gate is switched between OV and 2.5V in order to tum on and off the device. The source is connected to the ground and the drain terminal is connected to a resistor coupled to a supply voltage of 5V.

When the main gate is at OV, the enhancement MOS device is in off-condition. The voltage of the drift region under the first gate edge (which represents the source of the depletion MOS) is at an intermediate voltage value of about 2.5 V. The depletion MOS device sees a gate-source voltage of about OV. In this bias condition, the overall device behaves as a conventional MOS with a drain extension and the second gate has limited effect on its behavior.

However, when the main gate terminal is brought to 2.5 V, the enhancement MOS turns on and the voltage of the drift region under the first gate edge (which represent the source of the depletion MOS) drops to a voltage value of few mV. The depletion MOS sees a gate-source voltage of about 2.5V and accumulates carriers under its gate-oxide 18 drastically reducing the on-resistance of the whole device with respect to the same device without extra gate.

Similar considerations can be made in the case where the extra gate 17 is connected to the ground instead of a supply voltage. In this case the second gate depletes the drift region during the off-state conditions, without affecting the on-state operation of the device. When the main purpose of the extra gate is to enhance the carrier concentration in the drift region during the on-state operation mode, the gate region 17 is preferably made in n-type poly-silicon (for an n-channel device) and allows a strong reduction of the device on-resistance.

While, if the main function of the extra gate is to deplete the drift region during off-state condition, a p-type poly-silicon (for an n-channel device) is preferably used and the drain extension can be designed with shorter lengths and/or with a lower doping concentration with respect to a conventional LDMOS, maintaining the high voltage tolerance of the structure. Furthermore, the depletion of the drift region that takes place when the device is turning off, leads to the reduction of the first-gate to drain capacitance of the device. In both cases described above, the extra gate terminal can be realized also with metallic materials with an• appropriate work-function.

The structure of FIG. 3, therefore, combines the advantages of a LDMOS device structure which is able to sustain high drain biases while maintaining a low gate capacitance, with the low on-resistance of standard MOS devices connected in a cascade configuration. Furthermore, with the present invention, the drain to gate capacitance is reduced which leads to an even higher improvement of the dynamic device performance.

In order to reduce the capacitive coupling between the second gate and the drain terminal, the drift region under the second gate can be also eliminated. In this case the device has two drift regions spaced apart one from the other.

As discussed above, the extra gate terminal can be connected in different ways. All of these methods have advantages and disadvantages which must be carefully evaluated, based on the device application. For example, by connecting the extra gate to a supply voltage, it enhances the electron population in the drift region when the device is turned on reducing the on-resistance of the device. While, when the transistor is in off-state the device behaves as a conventional MOS device with a drain extension.

Instead, by connecting the extra gate to ground, it mainly depletes the drift region when the device is turned off reducing the gate to drain capacitance. The depletion effect of the extra gate enables the device to sustain a much higher drain bias with respect to a standard MOS device with drain extension. This feature introduces a new degree of freedom in the design of the drift region, which can be made shorter while maintaining the channel electric field in the safe range. When the transistor is in on-state the device behaves as a conventional MOS device with a drain extension.

When used in switching power converters, the second gate can be also coupled to the ground through a capacitor of adequate value. This is possible since the average of the capacitive current in the second gate is null throughout a period of switching, allowing an increase of the device efficiency, since no energy is dissipated in the second gate. By connecting the capacitor to a high impedance node for the initial voltage (e. g. a resistor divider from Vin to ground) the drive circuit of the device is much simplified. Alternative schemes are also possible, as it is obvious to anyone skilled in the art.

Another interesting configuration is obtained when the second gate is short-circuited with the drain terminal. In this case the capacitance between the drain and the second gate is completely eliminated and the dynamic performances of the device are greatly improved. However, in this case, the advantage in terms of DC on-resistance is less evident with respect to the previous configurations.

The present invention in the embodiment depicted in FIG. 3 can be obtained with a standard CMOS process. The extra gate can be formed in parallel with the first one simply modifying the masks layout. The same gate oxide can be used for both gate electrodes. This makes the present invention very cost attractive.

Another interesting method to implement this embodiment is to exploit the spacer of the first gate to determine the location where the second gate is formed. Starting from a conventional MOSFET with a drain extension where the first gate region has already been formed and the gate oxide layer has not been etched from the device surface, the second gate can be formed by means of a simple deposition step followed by a polish and an etch process steps to remove the deposited material from the undesired area. The advantage of this second technique is that the distance of the second gate from the first one is independent from the technology node. Obviously many other process variants can be used to obtain the embodiment described above. Similar process considerations still apply for all the other embodiments described herein.

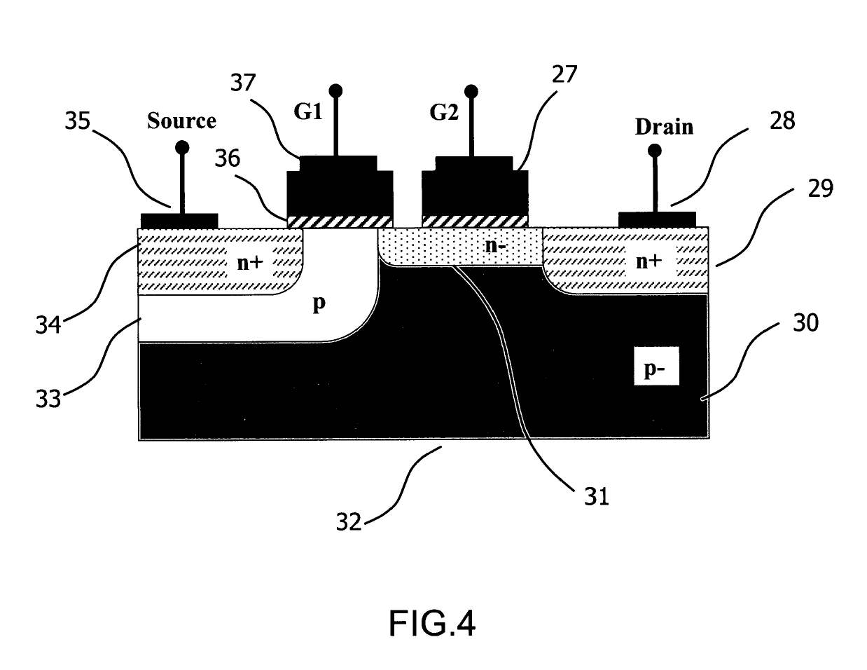

### B FIG. 4

In FIG. 4 is shown a second embodiment of the invention. This device structure has been obtained from an LDMOS by simply adding a second gate on the top of the drift region.

In this case, the channel length of the device is determined by the doping implants characteristics (e.g. impurity concentration, diffusivity and implants deepness) of the source and drain regions rather than the minimum feature size of the process technology used to realize the device. As mentioned above, this is a great advantage in power devices that usually are using process technologies that are not the most advanced, to reduce the fabrication cost.

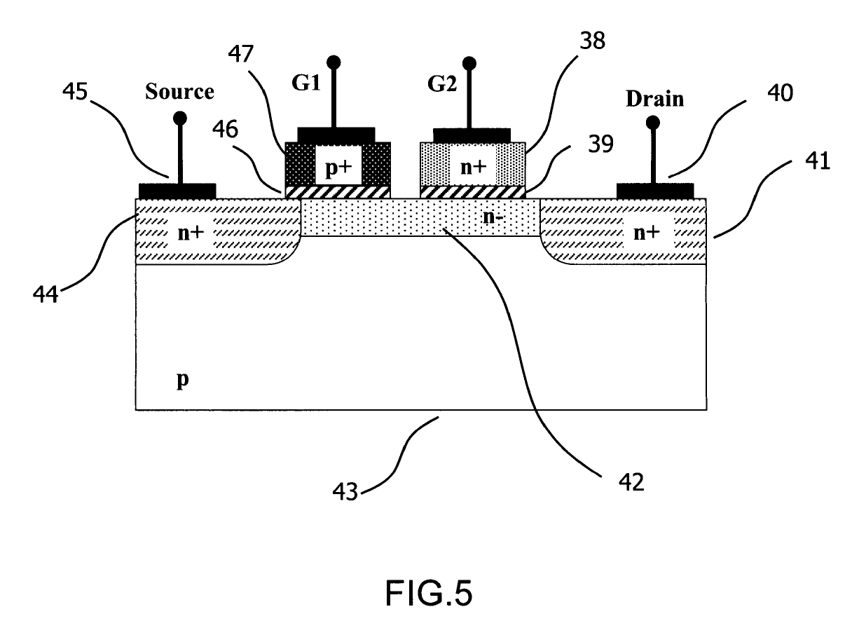

### C FIG. 5

FIG. 5 is depicting the cross-section view of a semiconductor device according to a third embodiment of the invention. This structure is similar to the one shown in FIG. 3, with the exception that the channel region has been doped with n-type impurities and the gate layer 47 is p-doped. In this case, the impurity scattering and the surface roughness scattering rates are greatly reduced with respect to the structure of FIG. 3. This structure allows therefore the improvement of the carrier mobility in the device maintaining a positive threshold voltage and, therefore; an enhancement MOS behavior.

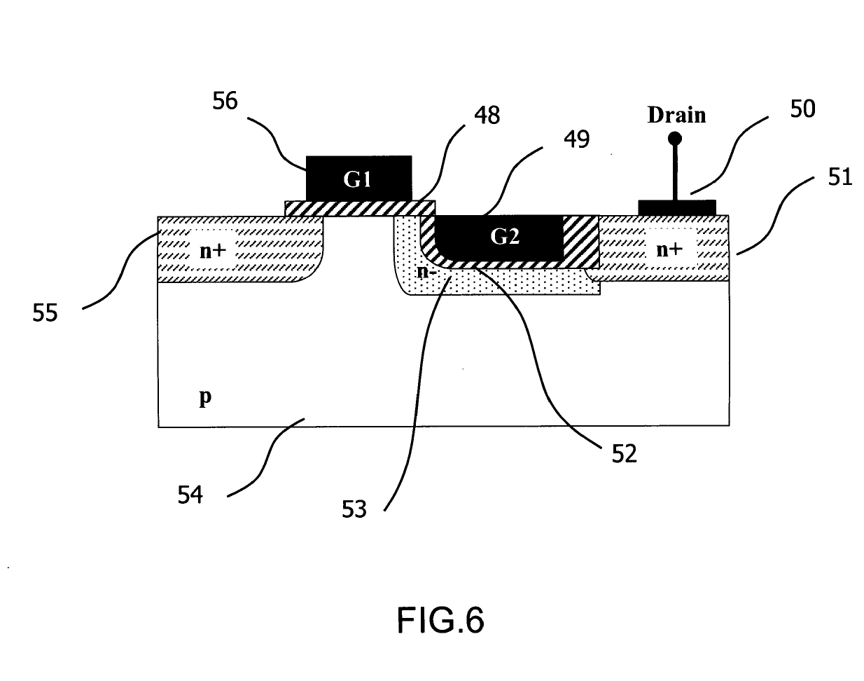

### D. FIG. 6

FIG. 6 illustrates a cross section of a fourth embodiment of the invention. This structure is similar to the one of FIG. 3, with the exception that the extra gate is buried in the silicon substrate. This configuration allows the reduction of the capacitive coupling between the two gate terminals, which leads to an improvement of the dynamic performance of the device.

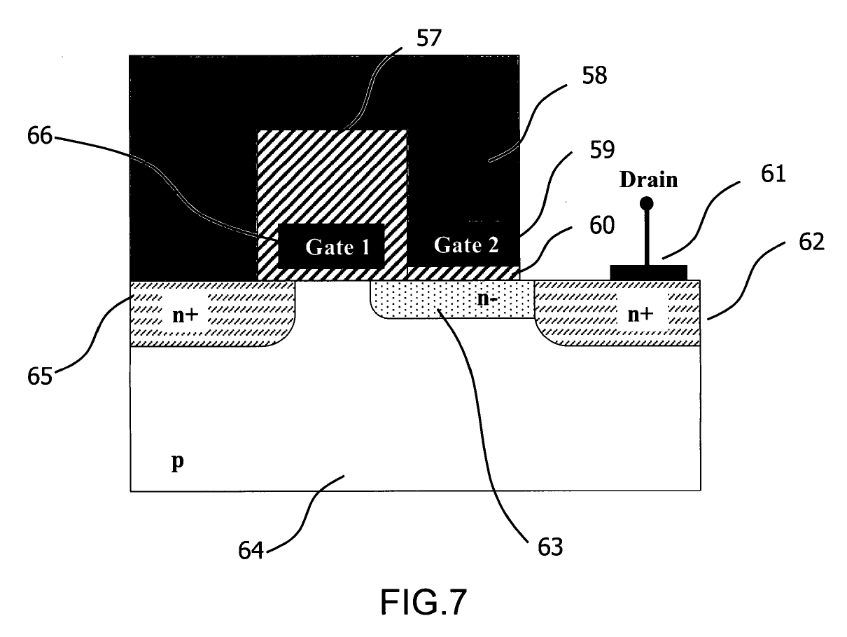

### E FIG. 7

In FIG. 7 a metal (or heavily doped poly-silicon) layer connecting the source with the extra gate is present. In this case the second gate is biased at the source voltage and only the main gate region is connected to an external terminal during the device operation.

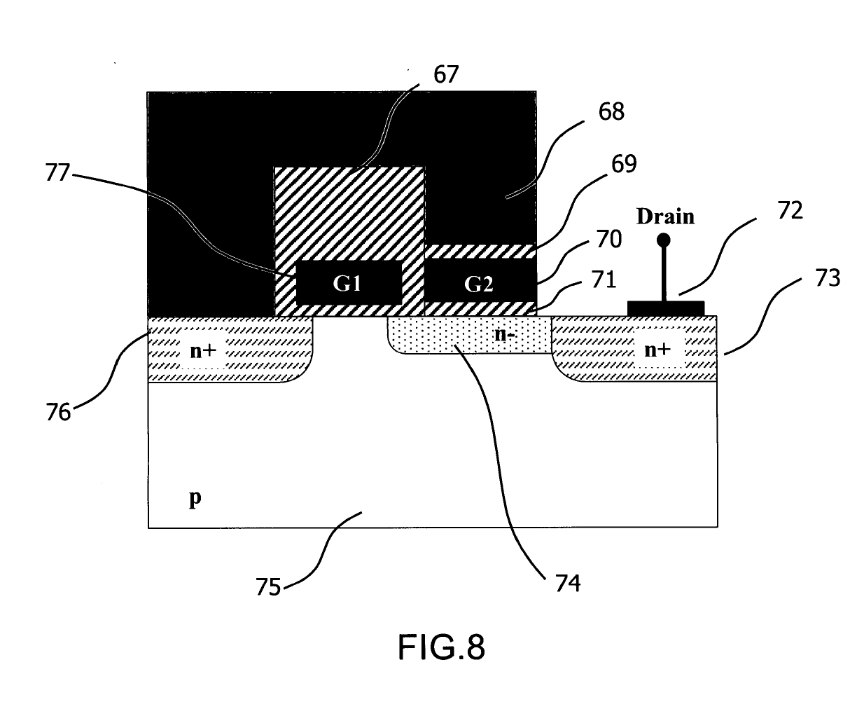

### F FIG. 8

In FIG. 8 is reported a structure similar to the one depicted in FIG. 7, with the difference that a thin dielectric layer 69 has been added between the metal (or heavily doped poly-silicon) layer 68 and the second gate 70. In this case the second gate is controlled by the capacitance composed by the layers 68, 69 and 70. By connecting the second gate to a high impedance for the initial voltage (e. g. a resistor divider from Vin to ground) the drive circuit of the device is much simplified.

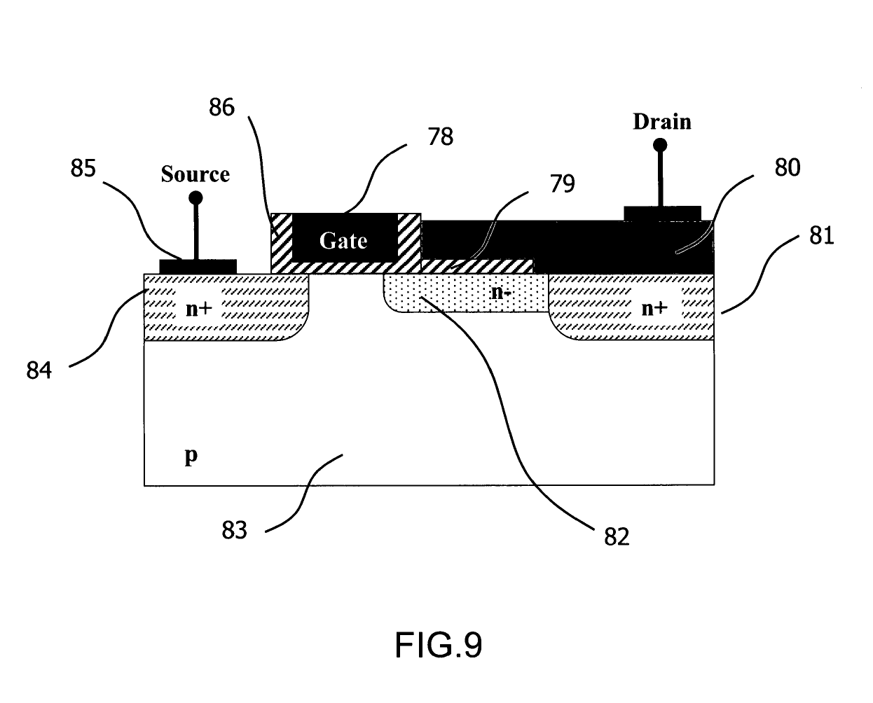

### G FIG. 9

FIG. 9 shows another embodiment of the invention, where the extra gate has been directly connected to the drain. This structural solution is very elegant and allows a strong improving of the device performances. The extra gate to drain capacitance has been indeed eliminated, which clearly leads to a great advantage in the dynamic device performance.

For all the FET structures described above, the p-channel version can be obtained by simply substituting the n-doped implants with p-type ones and vice-versa. As it is clear to those skilled in the art, the present invention can be used also in discrete devices and/or in vertical FET structures with simple modifications.

All the device structures described above can be realized in standard CMOS technology. Most of them do not even require additional process steps. This makes the present invention very cost attractive.

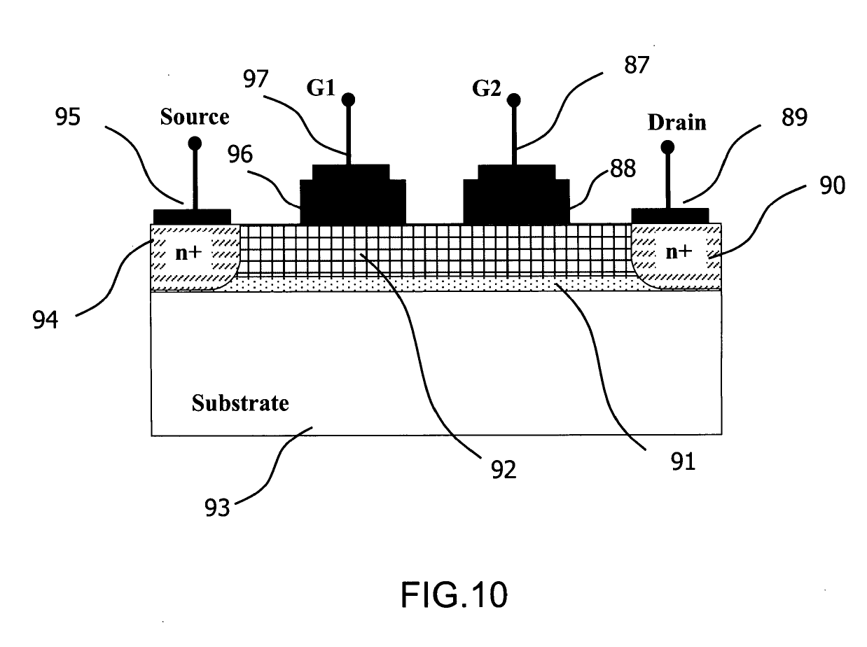

### H FIG. 10

As illustrated in FIG. 10, besides the CMOS technology, the present invention can be realized also with a High Electron Mobility Transistor structure including III-V compounds semiconductor materials of the periodic table in the fabrication process. This can be an attractive alternative to the Silicon MOSFET configuration in some particular applications. In this case the gate 96 can be done n or p-doped depending on whether the resulting device has to work in enhancement or in depletion mode, respectively. For the second gate 88, the same considerations for the MOS technology apply.

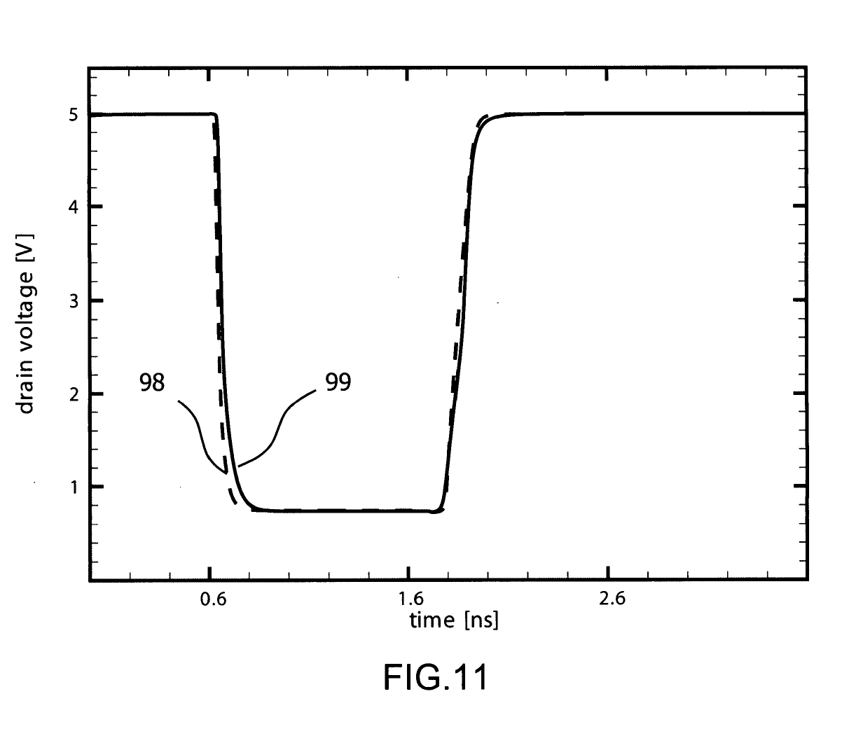

### I FIG. 11

The fact that the present invention offers lower specific Roson can be viewed as a means of producing more efficient power devices and therefore having less power to be dissipated for the same silicon area. But it could also be interpreted as a means to reduce the silicon area for the same on resistance. Another way to interpret the present invention is that the drain extension can be designed to sustain very high voltages without degrading the on-resistance of the device.

In FIG. 11 are reported the numerical simulation as result of the comparison performed between a conventional MOS with a drain extension and the same device, three times smaller, with an extra gate in according to the preferred embodiment of the invention. A resistive load has been placed between the drain and the supply voltage and a pulse voltage signal varying between 0 and 2.5V has been applied to the main gate terminal. In this analysis the second gate has been coupled to the ground through an external capacitor of 100 pF, while the load resistance used was 5 Ohms. The simulated devices, according to the present invention and the conventional MOS with drain extension, have a channel width of 1.6 and 5 mm, respectively. Both devices have a gate length of 0.25 μm.

As it can be seen from FIG. 11, where the drain voltage as a function of time is illustrated, the two simulated devices present the same on-resistance, even if the one according with the present invention (solid line 99) occupies less than one third of the silicon area required for the conventional MOS device (dashed line 98).

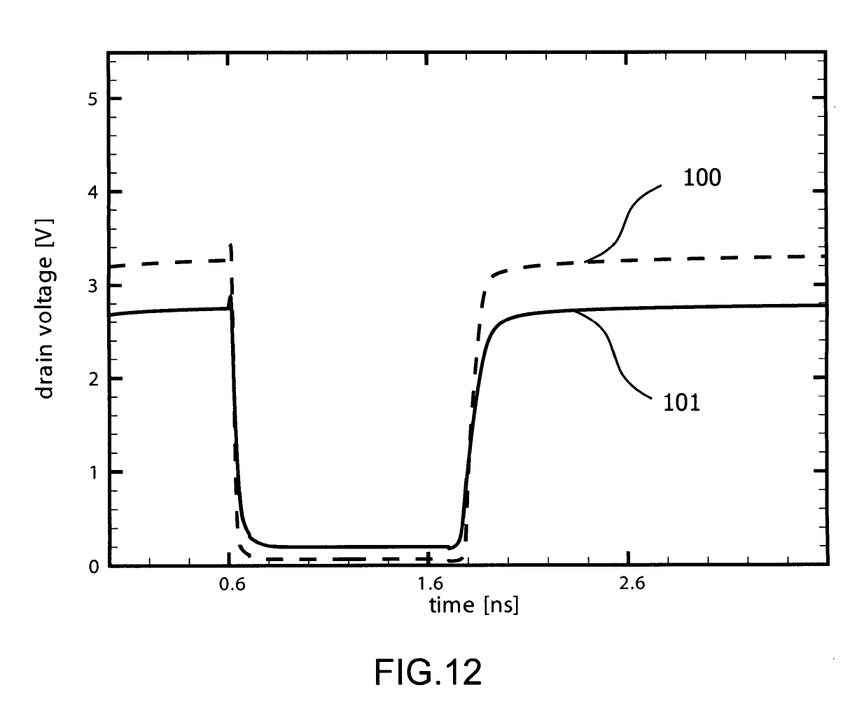

### J FIG. 12

The drift region length and doping concentration are the same in both devices and they were designed to maintain the voltage under the gate-drain edge around 2.5-3V. As it can be seen from FIG. 12, which illustrates the voltage in proximity of the lateral edge of the first gate of each device, the voltage drop on the first portion of the device (and therefore also the field under the gate edge) in the case of the present invention (solid line 101) is smaller than in the case of a conventional MOS with drain extension (dashed line 100).

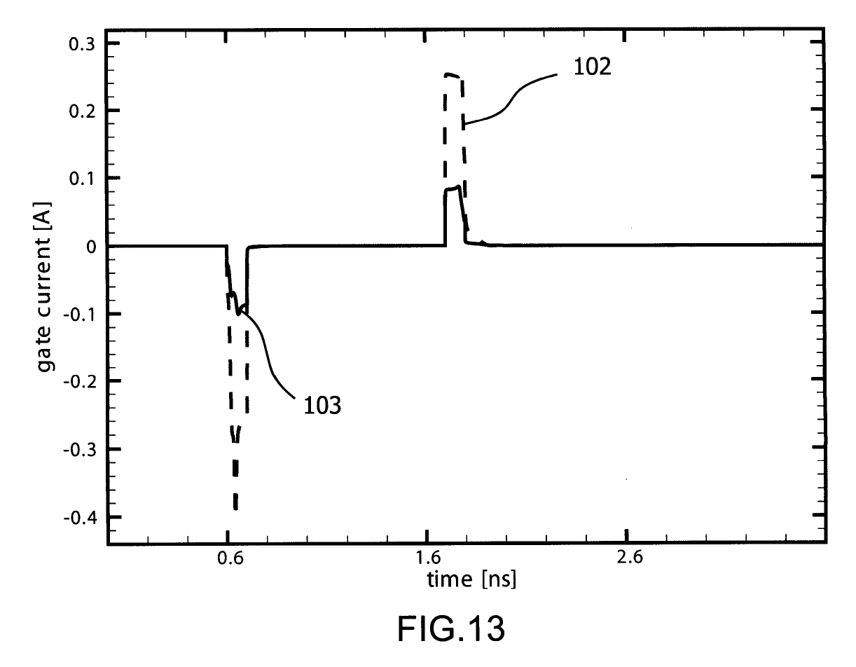

### K. FIG. 13

It is important to notice that also the gate current and therefore the switching losses of the present invention are reduced by a factor 3 or more as shown in FIG. 13. The peak of the gate current in the device according to the present invention (solid lines 103) is much smaller if compared with the one of the conventional MOS with drain extension (dashed line 102). As shown by the numerical simulations, the present invention improves the device performance by a factor 3 or more, which reflects a great reduction of the cost of the device when implemented in power circuit applications.

Although the present invention has been described above with particularity, this was merely to teach one of ordinary skill in the art how to make and use the invention. Many additional modifications will fall within the scope of the invention. Thus, the scope of the invention is defined by the claims which immediately follow.

What is claimed is:

1. (canceled)

2. A semiconductor field effect device comprising:
a semiconductor substrate layer of a first conductivity type;
a first region and a second region of a second conductivity type in the semiconductor substrate layer;
a drift region between the first region and the second region of the second conductivity type; and
a first gate region and a second gate region disposed above the semiconductor substrate layer; and
a non-insulative region connected to the first region, a portion of the non-insulative region being adjacent to the second gate region, wherein:
the second gate region is entirely above the drift region;
the first gate region is above a third region of the semiconductor substrate layer;
the second gate region is above a fourth region of the semiconductor substrate layer, the third region and the fourth region being non-overlapping regions with respect to a perspective perpendicular to the semiconductor substrate layer; and
the drift region is in physical contact with the first region or the second region.

3. The semiconductor field effect device of claim 2, wherein the drift region is in physical contact with the second region and isolated from the first region via a portion of the semiconductor substrate layer.

4. The semiconductor field effect device of claim 2, wherein the third region of the semiconductor substrate layer partially overlaps with the drift region with respect to a perspective perpendicular to the semiconductor substrate layer.

5. The semiconductor field effect device of claim 2, wherein the third region of the semiconductor substrate layer partially overlaps with the first region with respect to a perspective perpendicular to the semiconductor substrate layer.

6. The semiconductor field effect device of claim 2, further comprising:
an insulative layer between the second gate region and the portion of the non-insulative region.

7. The semiconductor field effect device of claim 2, further comprising:
a first insulative layer between the first gate region and the semiconductor substrate layer; and
a second insulative layer between the second gate region and the semiconductor substrate layer.

8. The semiconductor field effect device of claim 7, wherein the first insulative layer is part of an insulative region adjacent to the non-insulative region, wherein the non-insulative region is electrically isolated from the first gate region via the insulative region.

9. The semiconductor field effect device of claim 2, wherein the non-insulative region comprises metal or heavily-doped poly-silicon.
